(19) United States
(12) Patent Application Publication
(10) Pub. No.: US 2012/0238099 A1
(43) Pub. Date: Sep. 20, 2012

(54) METHOD OF MANUFACTURING ELECTRONIC PART

(75) Inventors: Takeshi SHUNDO, Mie (JP); Fumiki Aiso, Mie (JP)

(73) Assignee: KABUSHIKI KAISHA TOSHIBA, Tokyo (JP)

(21) Appl. No.: 13/235,439

(22) Filed: Sep. 18, 2011

(30) Foreign Application Priority Data
Mar. 18, 2011 (JP) 2011-060645

(51) Int. Cl. H01L 21/311

(52) U.S. Cl. 438/703; 257/E21.249

(57) ABSTRACT

According to one embodiment, a process target above a substrate is processed in order to produce a wiring pattern including dense wirings and sparse wirings. Next, a sacrificial film filled between wirings is formed in a region where the dense wirings are formed, and then an insulation film is formed above the substrate. A mask is formed such that a part of the region where the dense wirings are formed is exposed and a region where the sparse wirings are formed is exposed, and the insulation film is etched using the mask. Then, the sacrificial film is removed through a part of the region where the dense wirings are formed. Thereafter, an embedded insulation film is formed above the substrate to fill a gap between adjacent wirings in the region where the sparse wirings are formed.

### CROSS-REFERENCE TO RELATED APPLICATIONS

This application is based upon and claims the benefit of priority from the prior Japanese Patent Application No. 2011-60645, filed on Mar. 18, 2011; the entire contents of which are incorporated herein by reference.

### FIELD

Embodiments described herein relate generally to a method of manufacturing an electronic part.

### BACKGROUND

For example, in non-volatile semiconductor storage devices such as an NAND-type flash memory, if a memory cell is miniaturized to a fine size to achieve high integration, the distance between adjacent word lines is reduced. Therefore, parasitic capacitance between adjacent gate electrodes increases, resulting in the significant reduction in a writing speed.

Furthermore, with progress of miniaturization of semiconductor devices in recent years, a wiring is also miniaturized. In general, the periphery of wirings of a semiconductor device is surrounded by an insulation film, resulting in the occurrence of delay due to the parasitic capacitance between wirings. Therefore, in the related art, there has been proposed a method of lowering a dielectric constant of an insulation layer between wirings by forming an air gap between adjacent wirings.

In the related art, the air gap is formed between the adjacent wirings after the wirings are formed to be embedded in the insulation layer. However, a method of forming a wiring, for example, by etching a conductive film serving as a wiring layer such that sparse wirings and dense wirings coexist, forming air gaps at desired positions between the wirings, and embedding an insulation film at other positions has not been proposed.

### BRIEF DESCRIPTION OF THE DRAWINGS

FIG. 1 is an equivalent circuit diagram illustrating a portion of a memory cell array formed in a memory cell area of an NAND-type flash memory device;

FIG. 2 is a plan view illustrating a layout pattern of a portion of a memory cell area;

FIG. 3 is a sectional view taken along line A-A of FIG. 2; and

FIGS. 4A to 14B are diagrams schematically illustrating an example of a method of manufacturing an electronic part according to an embodiment.

### DETAILED DESCRIPTION

According to one embodiment, a process target, including a conductive material film, above a substrate is first processed to produce a wiring pattern including dense wirings, in which a distance between adjacent wirings is equal to or less than a predetermined value, and sparse wirings in which a distance between adjacent wirings is larger than the predetermined value. Next, a sacrificial film is formed above the substrate, above which the wiring pattern is formed, such that the sacrificial film fills between the adjacent wirings in a region where the dense wirings are formed. Then, the sacrificial film formed above the wiring pattern and the sacrificial film formed between the adjacent wirings in a region where the sparse wirings are formed are removed, while the sacrificial film filled between the adjacent wirings in the region where the dense wirings are formed is left. Thereafter, an insulation film is formed above the substrate including the wiring pattern and the remaining sacrificial film. Then, a mask is formed above the insulation film such that the insulation film is partially exposed at a part of the region where the dense wirings are formed and the insulation film is exposed at the region where the sparse wirings are formed, and the exposed insulation film is etched using the mask. Thereafter, the sacrificial film is removed through the part of the region where the dense wirings are formed, in which the insulation film has been etched away, so that an air gap is formed between the adjacent wirings in the region where the dense wirings are formed. After the air gap is formed between the adjacent wirings in the region where the dense wirings are formed, an embedded insulation film is formed above the substrate to fill a gap between the adjacent wirings in the region where the sparse wirings are formed.

Exemplary embodiments of a method of manufacturing an electronic part will be explained below in detail with reference to the accompanying drawings. The present invention is not limited to the following embodiments. Furthermore, the sectional view of a semiconductor device used in the following embodiment is schematically shown, and the relation between the thickness and the width of a layer, a ratio of the thickness of each layer, and the like may be different from the real. Moreover, a film thickness shown in the following description is for illustrative purposes only, and the present invention is not limited thereto.

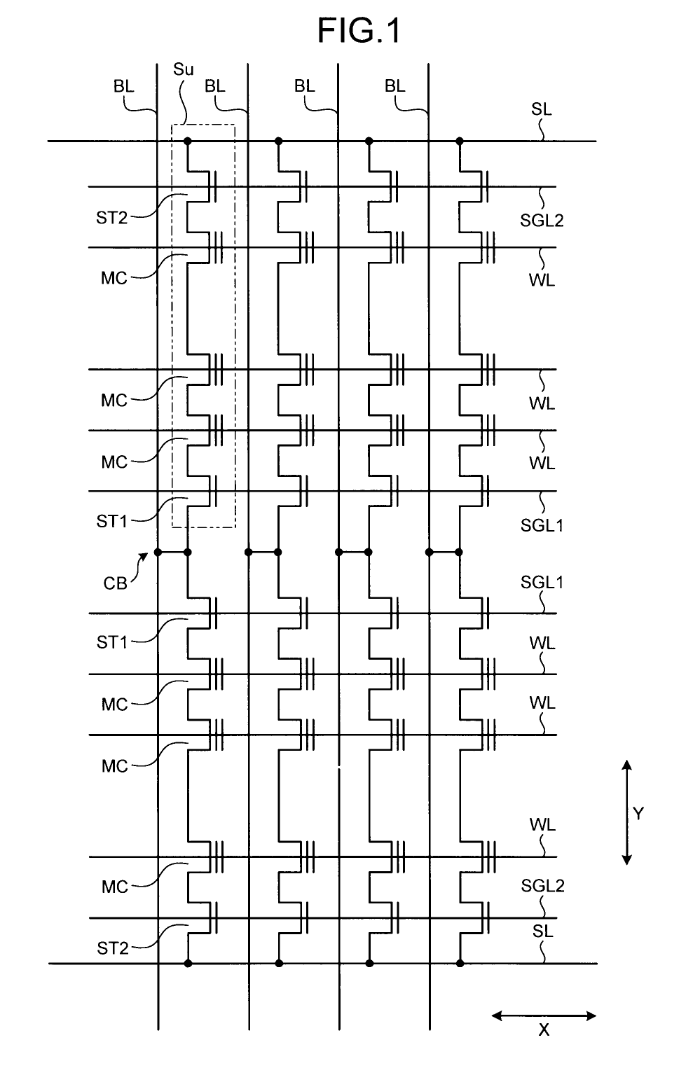

Hereinafter, a case will be described in which the embodiment is applied to an NAND-type flash memory. FIG. 1 is an equivalent circuit diagram illustrating a part of a memory cell array formed in a memory cell area of the NAND-type flash memory device. In FIG. 1, the right and left direction on the plane is defined as an X direction and the direction on the plane perpendicular to the X direction is defined as a Y direction. In a memory cell array of the NAND-type flash memory device, NAND cell units (memory units) Su which include two selection gate transistors ST1 and ST2 and a plurality of (e.g., 2ⁿ (n is a positive integer)) memory cell transistors (hereinafter, also referred to as memory cells) MC serially connected to one another in the Y direction (a bit line direction corresponding to a gate length direction) between the selection gate transistors ST1 and ST2 are arranged in a matrix shape. In the NAND cell unit Su, source/drain regions of adjacent memory cells MC are shared for use. Furthermore, one block is formed by a plurality of NAND cell units Su arranged in the X direction.

The memory cells MC arranged in the X direction (a word line direction corresponding to a gate width direction) of FIG. 1 are commonly connected to one another by word lines (control gate lines) WL. Furthermore, the selection gate transistors ST1 arranged in the X direction of FIG. 1 are commonly connected to one another by a selection gate line SGL1, and the selection gate transistors ST2 are commonly connected to one another by a selection gate line SGL2. A bit line contact CB is connected to a drain region of the selection gate transistor ST1. One end of the bit line contact CB is connected to a bit line BL extending in the Y direction of FIG. 1. Furthermore, the selection gate transistor ST2 is connected to a source line SL, which extends in the X direction of FIG. 1, via a source region.

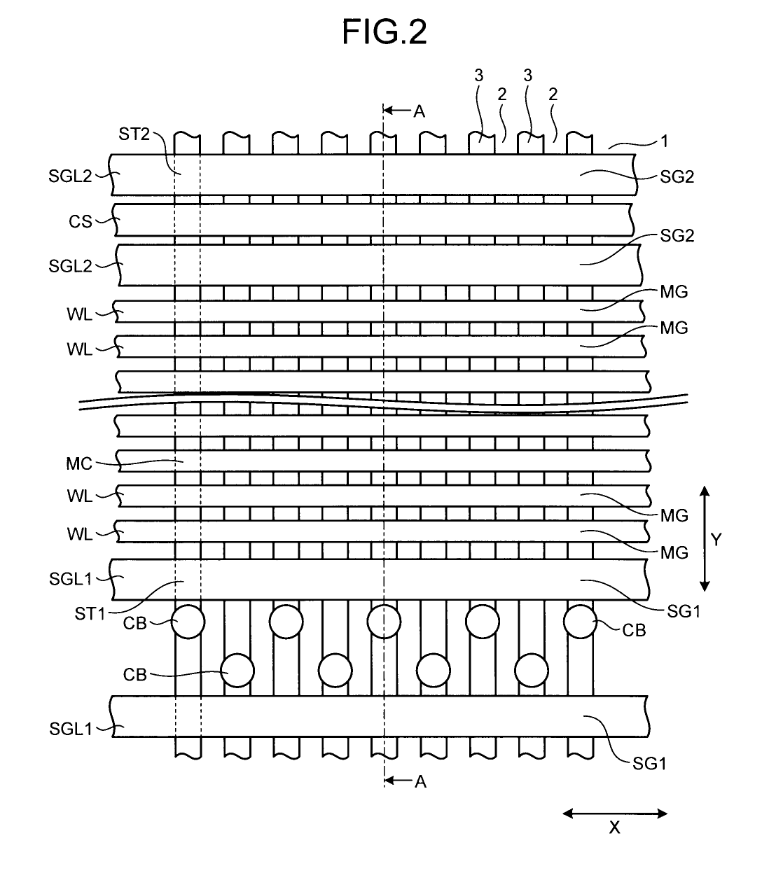

FIG. 2 is a plan view illustrating a layout pattern of a part of a memory cell area. In a substrate 1 as a semiconductor substrate, a plurality of shallow trench isolations (STIs) 2 as isolation regions extend in the Y direction of FIG. 2, and are formed in the X direction at a predetermined interval, and thus adjacent active regions 3 are isolated from one another in the X direction of FIG. 2. Word lines WL of the memory cells MC extend in the X direction of FIG. 2, which is perpendicular to the active regions 3, and are formed at a predetermined interval in the Y direction.

Furthermore, two selection gate lines SGL1 extending in the X direction of FIG. 2 are formed in parallel to each other while being adjacent to each other. Bit line contacts CB are formed in the active regions 3 between the two adjacent selection gate lines SGL1, respectively. In this example, the bit line contacts CB are arranged in adjacent active regions 3 in such a manner that the positions in the Y direction are alternately changed. That is, between the two selection gate lines SGL1, bit line contacts CB approaching one selection gate line SGL1 and bit line contacts CB approaching the other selection gate line SGL1 are alternately arranged, what is called, are arranged in a zigzag manner.

Similarly to the case of the selection gate lines SGL1, two selection gate lines SGL2 extending in the X direction of FIG. 2 are formed in parallel to each other at positions in which the selection gate lines SGL1 and a predetermined number of word lines WL exist. Source line contacts CS are arranged in the active regions 3 between the two selection gate lines SGL2.

Stack gate structures MG of the memory cells MC are formed on the active regions 3 crossing the word lines WL, and gate structures SG1 and SG2 of the selection gate transistors ST1 and ST2 are formed on the active regions 3 crossing the selection gate lines SGL1 and SGL2.

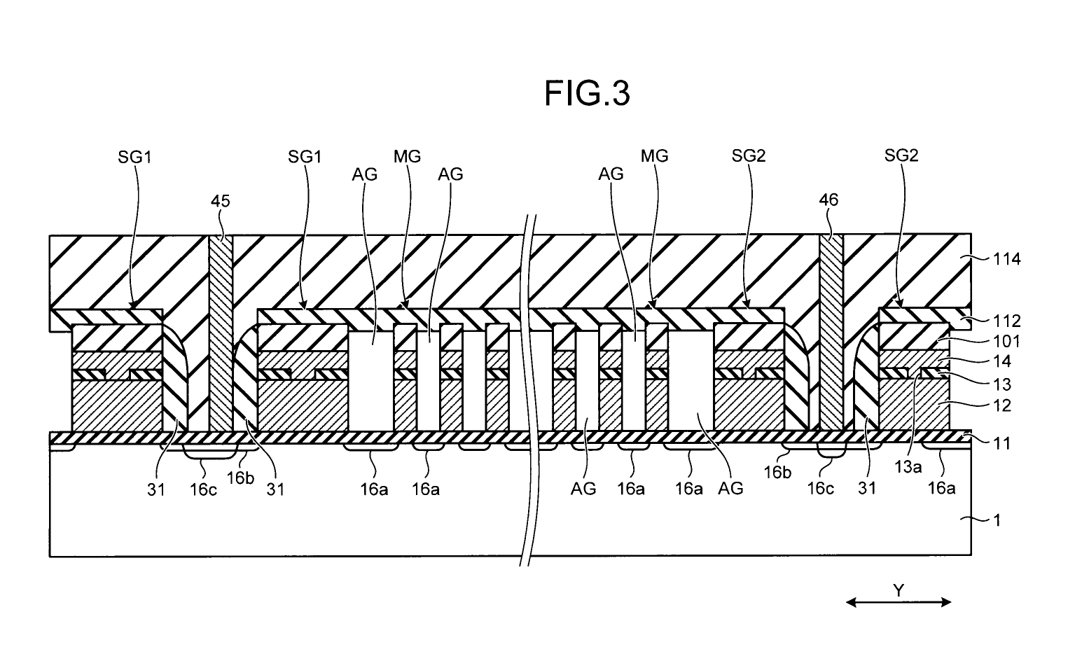

FIG. 3 is a sectional view taken along line A-A of FIG. 2. That is, FIG. 3 illustrates the gate structures SG1 and SG2 of the selection gate transistors ST1 and ST2 in the active regions 3 and the stack gate structures MG of the memory cells MC arranged between the two selection gate transistors ST1 and ST2. In FIG. 3, the stack gate structures MG of the memory cells MC and the gate structures SG1 and SG2 of the selection gate transistors ST1 and ST2, which are formed on the substrate 1 such as a silicon substrate, have a structure in which a floating gate electrode film 12, an inter-electrode insulation film 13, and a control gate electrode film 14 are sequentially stacked via a tunnel insulation film 11. In addition, the inter-electrode insulation film 13 of the gate structures SG1 and SG2 of the selection gate transistors ST1 and ST2 is formed with openings 13a through which the floating gate electrode film 12 is electrically connected to the control gate electrode film 14, and the control gate electrode film 14 is filled in the openings 13a. In this way, in the selection gate transistors ST1 and ST2, a gate electrode is constituted by the floating gate electrode film 12 and the control gate electrode film 14. Furthermore, a hard mask film 101 is formed on the gate structures SG1 and SG2 and the stack gate structure MG, wherein the hard mask film 101 includes a silicon oxide film, a silicon nitride film and the like.

As the tunnel insulation film 11, it is possible to use a thermal oxide film, a thermal oxynitride film, a chemical vapor deposition (CVD) oxide film, a CVD oxynitride film, an insulation film including Si therein, an insulation film having Si embedded like a dot, and the like. As the floating gate electrode film 12, it is possible to use polysilicon doped with N type impurities or P type impurities, a metal film using Mo, Ti, W, Al, Ta and the like, a poly metal film, a nitride film and the like. As the inter-electrode insulation film 13, it is possible to use a silicon oxide film, a silicon nitride film, an oxide-nitride-oxide (ONO) film with a stack structure of a silicon oxide film and a silicon nitride film, a high dielectric constant film such as an aluminum oxide film or a hafnium oxide film, a stack structure of a low dielectric constant film such as a silicon oxide film or a silicon nitride film and a high dielectric constant film, and the like. As the control gate electrode film 14, it is possible to use polysilicon doped with N type impurities or P type impurities, a metal film using Mo, Ti, W, Al, Ta and the like, a poly metal film, a stack structure of a polysilicon film and a metal silicide film, and the like.

Impurity diffusion regions 16a serving as source/drain regions are formed in the vicinity of the surface of the substrate 1 between the stack gate structures MG, between the stack gate structure MG and the gate structures SG1 and SG2, and the tunnel insulation film 11 is formed on the impurity diffusion region 16a. Furthermore, similarly to the impurity diffusion regions 16a, impurity diffusion regions 16b serving as source/drain regions are formed in the vicinity of the surface of the substrate 1 between adjacent gate structures SG1 and between adjacent gate structures SG2, respectively.

Between a pair of adjacent gate structures SG1 and between a pair of adjacent gate structures SG2, offset spacer films 31 including a silicon oxide film are formed on the sidewall surfaces of the gate structures SG1 facing each other and the gate structures SG2 facing each other, and the tunnel insulation film 11 is formed on the surface of the substrate 1 between the gate structures SG1 and between the gate structures SG2. Impurity diffusion regions 16c are formed in the vicinity of the surface of the substrate 1 between the offset spacer films 31 facing each other to reduce contact resistance of the bit line contact CB and the source line contact CS. The impurity diffusion region 16c has a width dimension smaller than that of the impurity diffusion region 16b, has a deep diffusion depth (depth of pn junction), and has a lightly doped drain (LDD) structure.

Furthermore, an insulation film 112 is formed to cover a column of the memory cells MC serially connected to one another in the bit line BL direction, and the upper parts of a pair of selection gate transistors ST1 and ST2 arranged at both ends of the column of the memory cells MC. An embedded insulation film 114 including an oxide film is filled in the inner side of a region surrounded by the offset spacer films 31 between the gate structures SG1 and between the gate structures SG2 on the insulation film 112. The embedded insulation film 114 is formed using a method such as a plasma CVD method as will be described later, thereby forming air gaps AGs between the stack gate structure MG and the gate structures SG1 and SG2 and between the stack gate structures MG.

No embedded material as air gaps AGs exists between the stack gate structure MG and the gate structures SG1 and SG2 and between the stack gate structures MG in the word line WL direction. The air gaps AGs are formed by providing air (or a vacuum state) between the stack gate structure MG and the gate structures SG1 and SG2 and between the stack gate structures MG, wherein the air is a dielectric material and has a very small dielectric constant. In this way, it is possible to reduce coupling capacitance between cells.

In detail, the insulation film 112 is not formed in trenches formed between the stack gate structure MG and the gate structures SG1 and SG2 and between the stack gate structures MG, and the upper portions of the trenches are closed by the insulation film 112, resulting in the formation of the air gaps AGs. That is, the lateral sides of the floating gate electrode film 12, the inter-electrode insulation film 13, and the control gate electrode film 14 are exposed.

A contact plug 45 reaching the surface of the substrate 1 from the upper surface of the embedded insulation film 114 is formed between adjacent the gate structures SG1 arranged at one end of the column of the memory cells MC. The contact plug 45 corresponds to the bit line contact CB, adjacent bit line contacts CB are alternately arranged in a zigzag manner as described above, and the contact plug 45 is formed at a position approaching the right side of FIG. 3. Furthermore, a contact plug 46 reaching the surface of the substrate 1 from the upper surface of the embedded insulation film 114 is formed between adjacent the gate structures SG2 arranged at the other end of the column of the memory cells MC. The contact plug 46 corresponds to the source line contact CS, and crosses between the bit lines BL.

In the NAND-type flash memory with the stack gate structure MG and the gate structures SG1 and SG2, the air gap AG with air (also including a vacuum state) with a very small dielectric constant is provided between adjacent word lines WL, so that it is possible to significantly reduce coupling capacitance between the adjacent word lines WL. In this way, it is possible to reduce inter-wiring capacitance, increase a voltage applied to the tunnel insulation film 11, and prevent a data writing speed from being reduced.

Furthermore, the embedded insulation film 114 is filled between the adjacent the gate structures SG1 or between the adjacent the gate structures SG2, thereby preventing the occurrence of void. Even when the bit line contact CB or the source line contact CS is formed in the region, it is possible to prevent short between adjacent selection gate transistors ST1 or between adjacent selection gate transistors ST2.

As described above, in the embodiment, the air gap AG is formed between adjacent wirings in a region where wirings with a fine line width are densely arranged, and the embedded insulation film 114 is filled in a region where wirings with a thick line width are sparsely arranged (isolated) without forming the air gap AG between adjacent wirings. At this time, the air gap AG is formed when the distance between the adjacent wirings is about twice as long as the line width of the finest wiring, and the embedded insulation film 114 is filled when the distance is larger than twice the line width of the finest wiring. Furthermore, the wiring may be an arrangement of the stack gate structure MG of the memory cell transistors MC and the gate structures SG1 and SG2 of the selection gate transistors ST1 and ST2 in a non-volatile semiconductor storage device such as an NAND-type flash memory as illustrated in the above example, or an arrangement of wirings made of a normal conductive material.

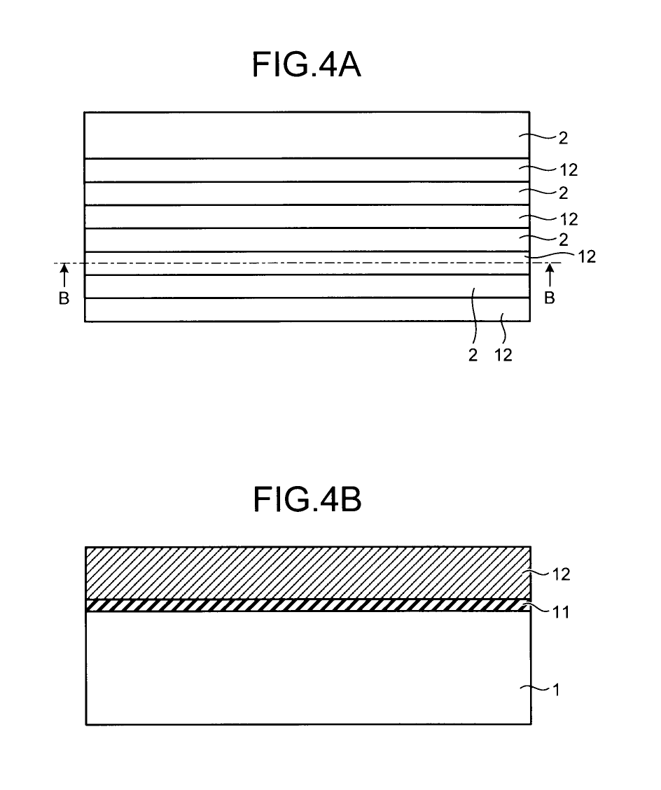

Next, a manufacturing method of electronic parts with the above structure will be described by employing the non-volatile semiconductor storage device as an example. FIGS. 4A to 14B are diagrams schematically illustrating an example of the manufacturing method of the electronic parts according to the embodiment. In detail, FIGS. 4A to 14A are plan views, and FIGS. 4B to 14B are sectional views taken along lines B-B of FIGS. 4A to 14A, respectively.

First, as illustrated in FIGS. 4A and 4B, the tunnel insulation film 11 and the floating gate electrode film 12 are formed on the substrate 1 such as a silicon substrate. The tunnel insulation film 11 can be formed using a method such as thermal oxidation, and the floating gate electrode film 12 can be formed using a film formation method such as a CVD method. Next, patterning is performed to isolate adjacent memory units to be formed later from each other using a photolithography technique and an etching technique, trenches (not illustrated) extending in the bit line BL direction and reaching the semiconductor substrate are formed, and an insulation film is filled in the trenches to form a STI 2.

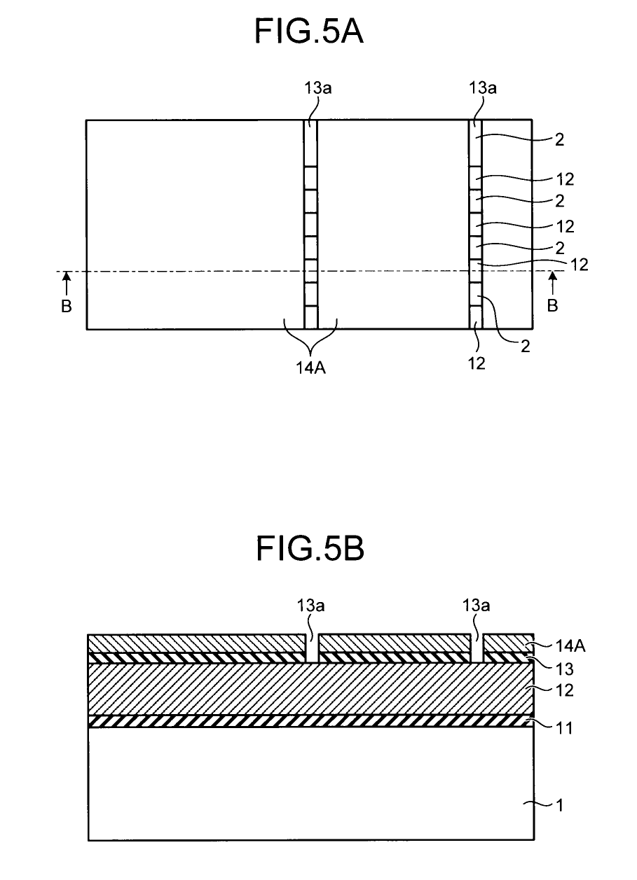

Then, as illustrated in FIGS. 5A and 5B, the inter-electrode insulation film 13 and a first conductive film 14A constituting a part of the control gate electrode film (word line) 14 is sequentially formed using a film formation method such as a CVD method or a sputtering method. Next, the openings 13a are formed in regions, where the gate structures SG1 and SG2 of the selection gate transistors ST1 and ST2 are to be formed later, by using a lithography technique and an etching technique, and a part of the first conductive film 14A and the inter-electrode insulation film 13 is removed. The openings 13a are formed such that the floating gate electrode film 12 is exposed.

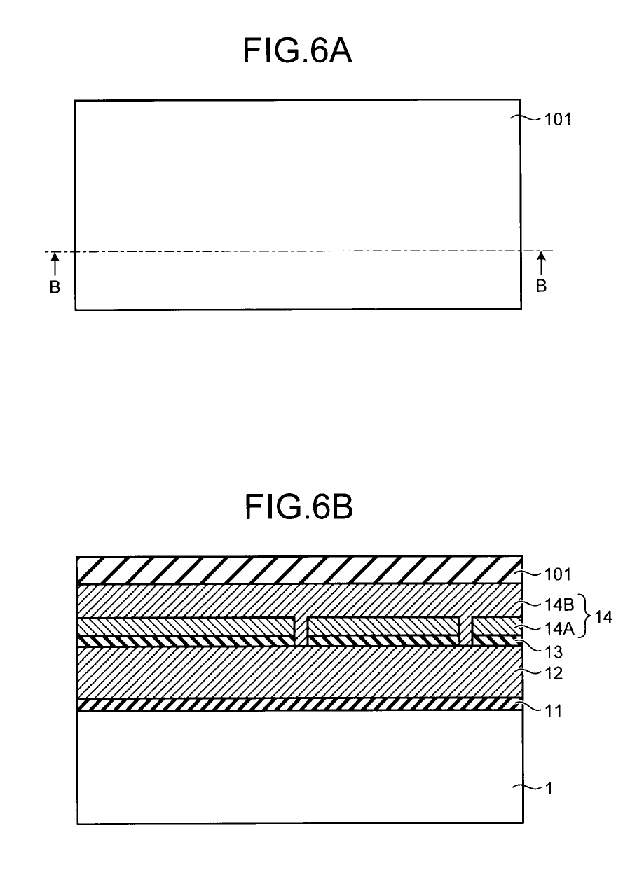

Then, as illustrated in FIGS. 6A and 6B, a second conductive film 14B constituting a part of the control gate electrode film 14 is formed using a film formation method such as a CVD method or a sputtering method. Here, the control gate electrode film 14 is formed by the first conductive film 14A and the second conductive film 14B in a region where the stack gate structure MG of the memory cells MC is to be formed later. In the following drawings, both the first conductive film 14A and the second conductive film 14B are integrally illustrated as the control gate electrode film 14. Furthermore, in a region where the gate structures SG1 and SG2 of the selection gate transistors ST1 and ST2 are formed, the floating gate electrode film 12 and the control gate electrode film 14 (the first conductive film 14A and the second conductive film 14B) are electrically connected to each other, and serve as a gate electrode. Next, the hard mask film 101 is stacked on the control gate electrode film 14 to be used later at dry etch processing.

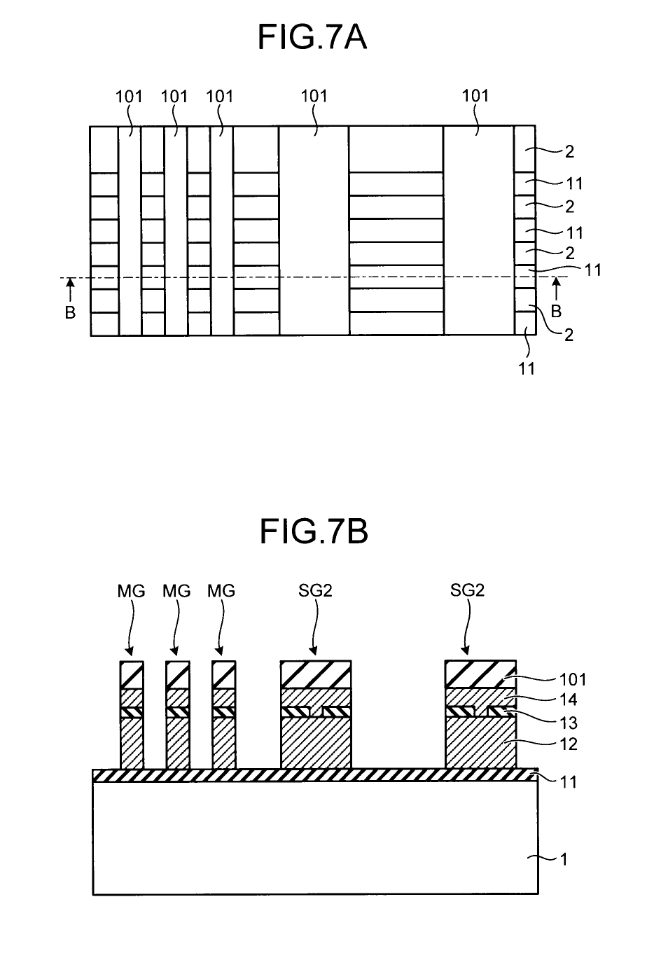

Then, a resist pattern for forming the stack gate structure MG and the gate structures SG1 and SG2 is formed using a photolithography technique. Next, as illustrated in FIGS. 7A and 7B, the hard mask film 101 is first etched using the resist pattern as a mask through a reactive ion etching (RIE) method, and then the control gate electrode film 14, the inter-electrode insulation film 13, and the floating gate electrode film 12 are etched using the hard mask film 101 as a mask. In this way, the selection gate transistors ST1 and ST2 and the memory cells MC, which are adjacent in the bit line BL direction, are isolated from each other, so that the stack gate structure MG and the gate structures SG1 and SG2 are formed. Here, the distance between the stack gate structures MG is approximately the same as the wiring width of a stack gate structure MG (word line) with the finest wiring width in a processing region, the distance between the stack gate structure MG and the gate structures SG1 and SG2 is larger than the wiring width of the stack gate structure MG and about twice as long as the wiring width of the stack gate structure MG, and the distance between the gate structures SG1 or between the gate structures SG2 is larger than twice the wiring width of the stack gate structure MG. Here, stack gate structures MG with a wiring width of 15 nm are formed with a pitch of 30 nm, and the interval between the stack gate structure MG and the gate structures SG1 and SG2 is set to 30 nm.

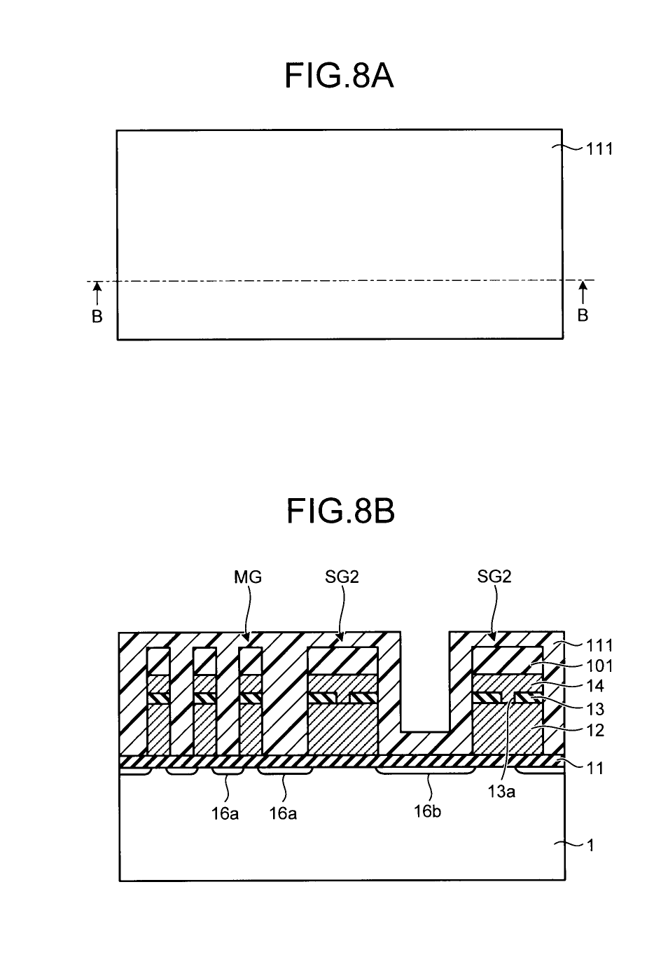

Then, as illustrated in FIGS. 8A and 8B, ions are implanted between the stack gate structures MG, between the stack gate structure MG and the gate structures SG1 and SG2, between the gate structures SG1, and between the gate structures SG2, and are activated, thereby forming the impurity diffusion regions 16a and 16b corresponding to the source/drain regions of the memory cells MC and the selection gate transistors ST1 and ST2.

Moreover, a sacrificial film 111 is formed above the entire surface of the substrate 1 including the stack gate structure MG and the gate structures SG1 and SG2 using a coating method. As the sacrificial film 111, for example, it is possible to use a carbon polymer film and the like, which are formed using a spin coating method. Here, the thickness of the sacrificial film 111 is adjusted such that the sacrificial film 111 is completely filled between the stack gate structures MG and between the stack gate structure MG and the gate structures SG1 and SG2, but is not completely filled between the gate structures SG1 and between the gate structures SG2. In detail, it is preferable that the thickness of the sacrificial film 111 is set to be in the range of from the half to the same level of the wiring width of the stack gate structure MG.

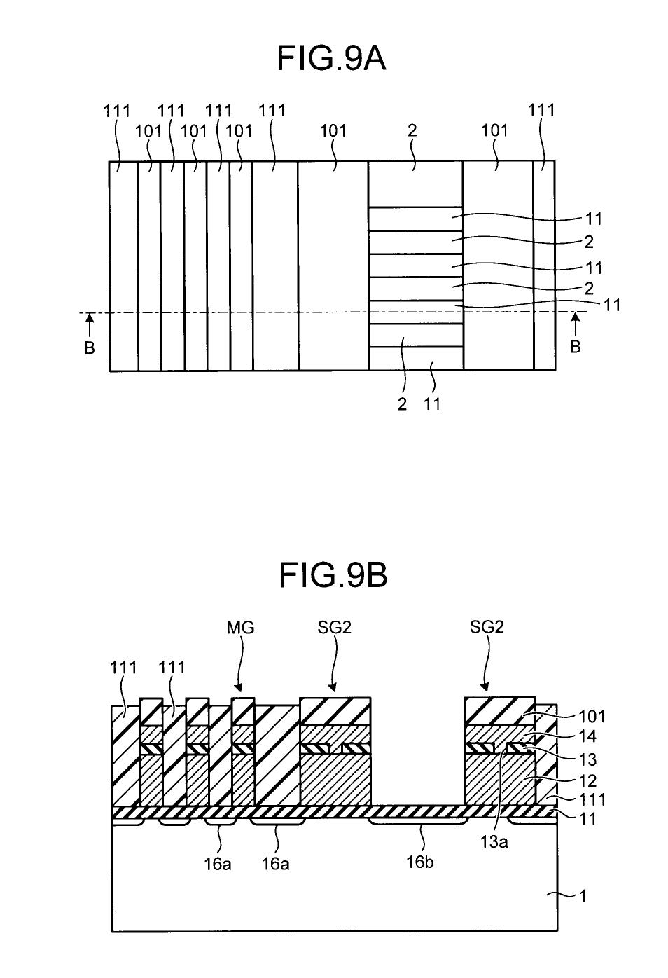

Then, as illustrated in FIGS. 9A and 9B, an ashing process is performed, so that only a sacrificial film 111 filled between dense wirings (between the stack gate structures MG and between the stack gate structure MG and the gate structures SG1 and SG2) is allowed to remain, and a sacrificial film 111 formed at other positions is removed. According to the ashing process, for example, the substrate 1 is arranged in an atomic layer deposition (ALD) apparatus to be used later and an oxygen plasma process is performed at a room temperature in the ALD apparatus. At this time, the oxygen plasma process is performed for a time longer than a formation time of an insulation film to be formed later in the same processing chamber, so that only the sacrificial film 111 filled between the stack gate structures MG and between the stack gate structure MG and the gate structures SG1 and SG2 is allowed to remain, and the sacrificial film 111 formed at other positions is removed using the ashing process.

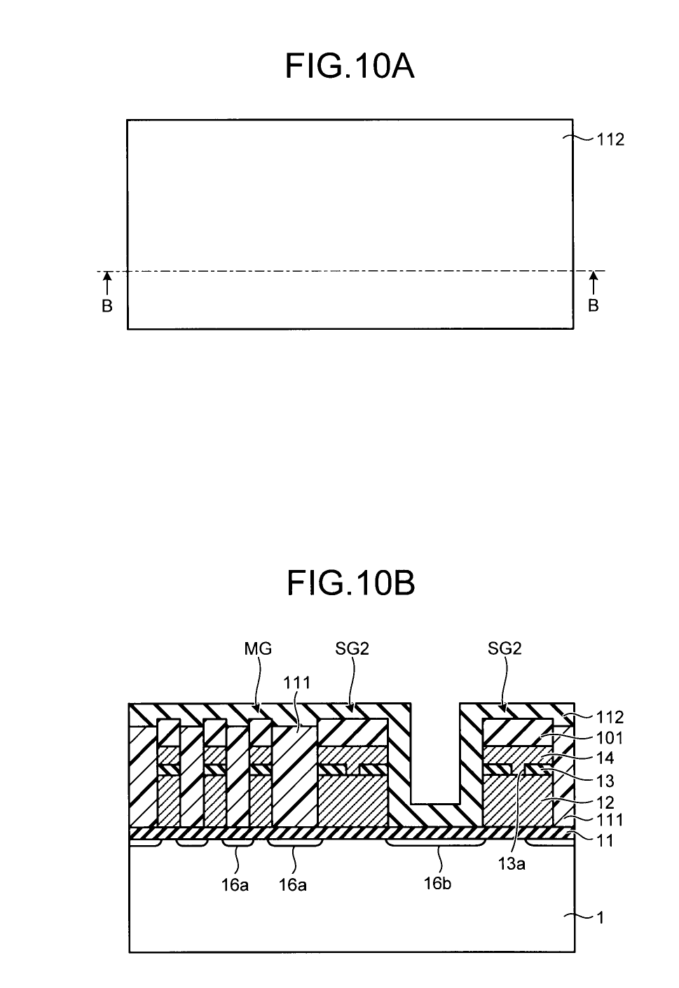

Then, as illustrated in FIGS. 10A and 10B, the insulation film 112 is formed above the entire surface of the substrate 1 using an ALD method. As the insulation film 112, for example, it is possible to use a silicon oxide film. Here, using an ALD method, oxygen plasma and, for example, diisopropylamino silane as silicon raw material gas are allowed to alternately flow at a low temperature around a room temperature to 100° C., so that a process of forming the insulation film 112 is performed. For example, the insulation film 112 with a thickness of 15 nm to 20 nm is formed. Between adjacent gate structures SG1 and between adjacent gate structures SG2, the insulation film 112 is formed to cover the lateral sides of exposed gate structures SG1 and SG2 and the bottom parts between the adjacent gate structures SG1 and between the adjacent gate structures SG2. In the other portions, the insulation film 112 is formed to cover the upper surfaces of the gate structures SG1 and SG2, the upper surface of the stack gate structure MG, and the upper surface of the sacrificial film 111.

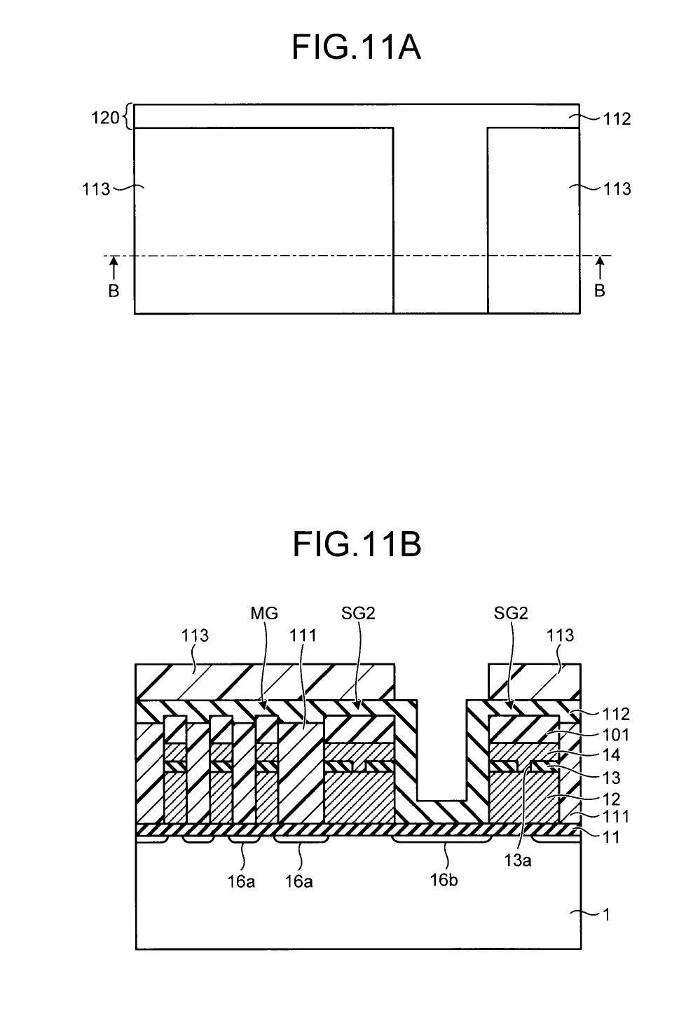

Then, as illustrated in FIGS. 11A and 11B, resist 113 is applied on the insulation film 112, and patterning is performed to cover a cell region, other than between the adjacent gate structures SG1 and between the adjacent gate structures SG2, by using a photolithography technique, thereby forming a mask pattern. The mask pattern is formed to cover the cell region. However, as illustrated in FIG. 11A, the mask pattern is not formed at an end (a drawing part) 120 in the word line direction. In such a case, since the mask pattern covers only the cell region, the mask pattern can also be formed in a relatively inexpensive exposure apparatus with a low resolution.

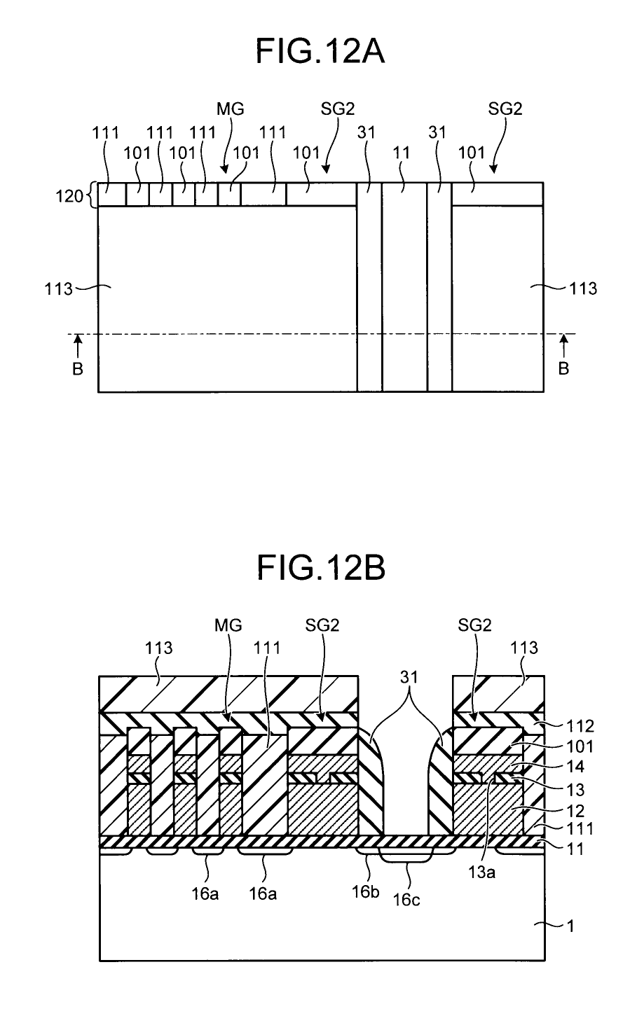

Then, as illustrated in FIGS. 12A and 12B, the insulation film 112 existing between the adjacent gate structures SG1 and between the adjacent gate structures SG2 is etched using the resist 113 as a mask through anisotropic etching such as RIE. Here, the etching process is performed to the extent that the insulation film 112 formed at the bottom parts between the adjacent gate structures SG1 and between the adjacent gate structures SG2 is removed. In this way, the offset spacer film 31 is formed at the lateral sides of the gate structures SG1 and SG2. Furthermore, the insulation film 112 of the drawing part 120 in a cell region not applied with the resist 113 is also removed, so that the sacrificial film 111 is exposed. Next, impurities are injected into the surface layer of the substrate 1 between the adjacent gate structures SG1 and between the adjacent gate structures SG2 using an ion implantation method, and are activated using a heat treatment, thereby forming the impurity diffusion region 16c for attenuating a channel electric field.

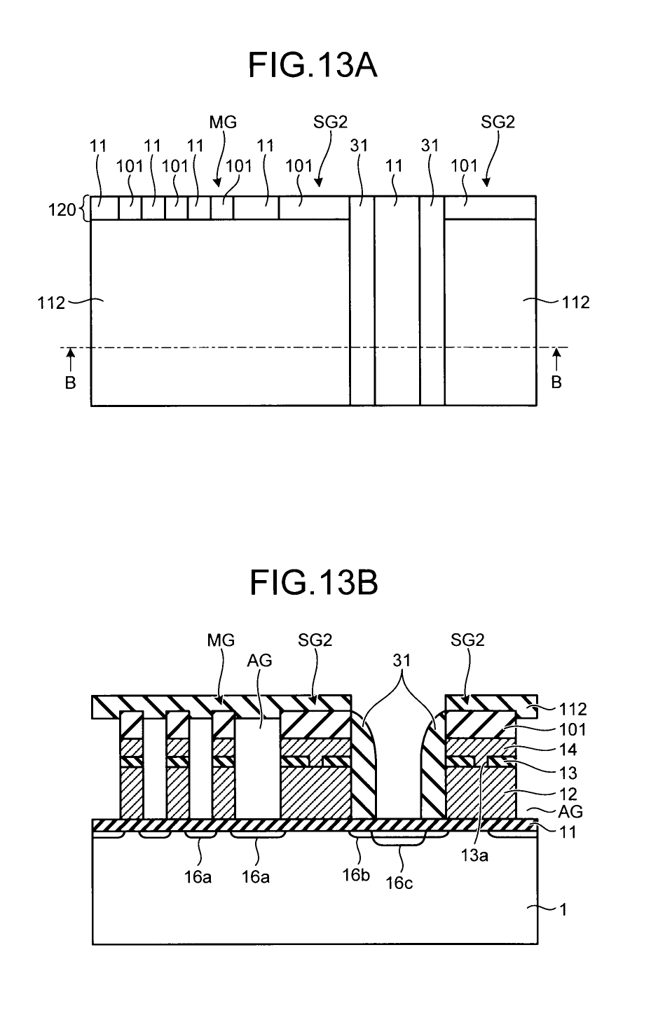

Then, as illustrated in FIGS. 13A and 13B, both the resist 113 on the insulation film 112 and the sacrificial film 111, which is filled between the stack gate structures MG and between the stack gate structure MG and the gate structures SG1 and SG2, are removed through an ashing process using oxygen plasma. When a carbon polymer film is used as the sacrificial film 111, since the sacrificial film 111 is very low resistance against oxygen asking, the sacrificial film 111 is easily removed through the drawing part 120 through which the sacrificial film 111 is exposed.

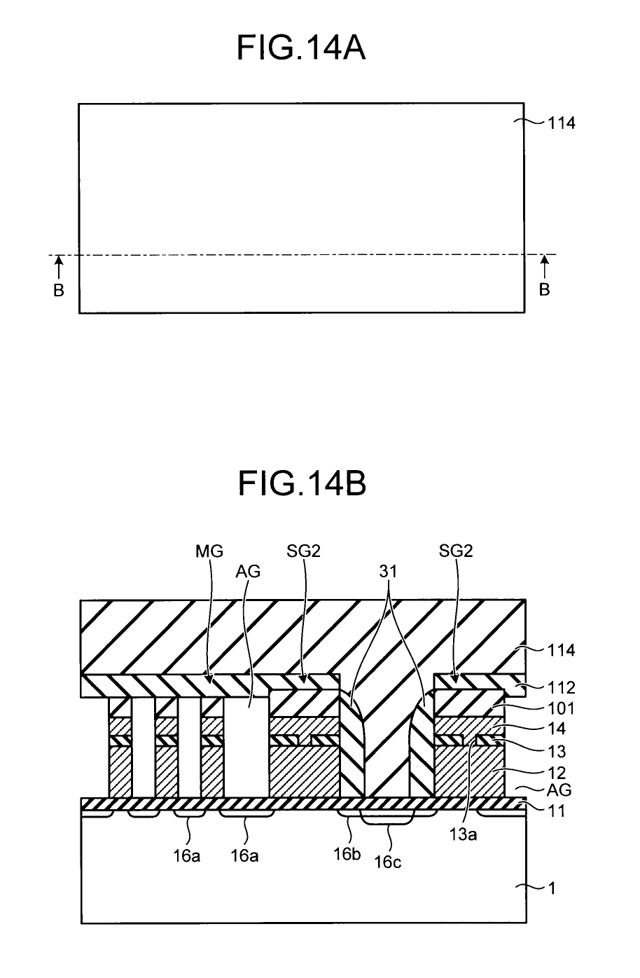

Then, as illustrated in FIGS. 14A and 14B, the embedded insulation film 114 is formed on the entire surface of the substrate 1 using a method such as a plasma CVD method. Here, the embedded insulation film 114 is filled in the drawing part 120, between the adjacent gate structures SG1, and between the adjacent gate structures SG2. At this time, since the offset spacer film 31 at the lateral sides of the gate structures SG1 and SG2 has a tapered shape at the upper end thereof and the condition can be set under low bias with relatively good embedding property without forming void at the drawing part 120, it is possible to form the embedded insulation film 114 with no void between the adjacent gate structures SG1 and between the adjacent gate structures SG2. Next, as illustrated in FIG. 3, the contact plugs 45 and 46 reaching the surface of the substrate 1 from the upper surface of the embedded insulation film 114 are formed between the adjacent gate structures SG1 and between the adjacent gate structures SG2.

So far, the case has been described in which empty spaces (air gaps AGs) are formed between the stack gate structures MG and between the stack gate structure MG and the gate structures SG1 and SG2 including densely arranged wirings wholly. However, the mask pattern including the resist 113 illustrated in FIGS. 11A and 11B may be changed, so that an empty space can be selectively formed between desired wirings in a region including the densely arranged wirings. For example, when the mask pattern is formed to cover the cell region, if the mask pattern is not formed between the stack gate structure MG and the gate structures SG1 and SG2 as well as between the adjacent gate structures SG1, between the adjacent gate structures SG2, and the drawing part 120, it is possible to fill the embedded insulation film 114 in spaces generated by removing the sacrificial film 111 even between the stack gate structure MG and the gate structures SG1 and SG2, similarly to the drawing part 120. Moreover, the embedded insulation film 114 may be filled between desired stack gate structures MG by changing the mask pattern. While an empty space can be formed between arbitrary wirings in the region including the densely arranged wirings, the embedded insulation film 114 can be filled between other wirings.

Furthermore, in the above embodiment, the case has been described in which the gate electrode of the memory cell MC of the NAND-type flash memory is used as an example of dense wirings, the gate electrode of the selection gate transistors ST1 and ST2 is used as an example of sparse wirings, an interlayer dielectric film is filled only between adjacent selection gate transistors ST1 and between adjacent selection gate transistors ST2, and an air gap is formed between other gate electrodes. However, as well as the non-volatile semiconductor storage device as described above, the above-mentioned embodiment can be applied to a manufacturing method of other semiconductor devices at the time of the formation of a gate electrode of a general semiconductor device, at the time of the formation of a memory cell of a cross-point type memory such as a resistive random access memory (ReRAM) and the like, at the time of the formation of a wiring used in a semiconductor device, and the like.

In the embodiment, after the sacrificial film 111 is formed between wirings such that the sacrificial film 111 is filled between dense wirings and is not completely filled between sparse wirings, the sacrificial film 111 on the wiring and between the sparse wirings is removed, the substrate including the wirings and the sacrificial film 111 is covered by the insulation film 112, the insulation film 112 in the vicinity of wiring ends is removed, the sacrificial film 111 is removed therefrom, and then the embedded insulation film 114 is formed to be filled between the sparse wirings. In this way, it is possible to form a sufficient empty space between adjacent dense wirings, and fill the embedded insulation film 114 with no void between adjacent sparse wirings. Furthermore, simultaneously to the ashing process of the resist 113 used when removing the insulation film 112 in the vicinity of wiring ends, since the sacrificial film 111 is removed to form the air gap AG, it is possible to efficiently remove the resist 113 and the sacrificial film 111.

Furthermore, since an oxide film is not deposited at the lateral sides of dense wirings, a metal film can be prevented from being oxidized without an increase of capacitance due to the oxide film. Moreover, since the embedded insulation film 114 is formed using a plasma CVD method with low bias, the embedded insulation film 114 with no void can be formed between sparse wirings, and no fixed charge is formed as with a coating-type insulation film. As a consequence, when a wiring, for example, is the stack gate structure MG of the NAND-type flash memory, it is possible to suppress the influence of switching characteristics due to the fixed charge.

Furthermore, in the case of the NAND-type flash memory, the insulation film 112 serving as a cover of the sacrificial film 111 is used as the offset spacer film 31 by an etching process at the lateral sides between adjacent gate structures SG1 and between adjacent gate structures SG2, it is possible to suppress a short channel effect in the selection gate transistors ST1 and ST2. Moreover, since the offset spacer film 31 including an insulation film (an oxide film) formed at a low temperature is modified by oxygen plasma at the time of ashing, it is possible to improve a leak current.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing an electronic part, the method comprising:
processing a process target, including a conductive material film, above a substrate so as to produce a wiring pattern including dense wirings, in which a distance between adjacent wirings is equal to or less than a predetermined value, and sparse wirings in which a distance between adjacent wirings is larger than the predetermined value;
forming a sacrificial film above the substrate, above which the wiring pattern is formed, such that the sacrificial film fills between the adjacent wirings in a region where the dense wirings are formed;
removing the sacrificial film formed above the wiring pattern and the sacrificial film formed between the adjacent wirings in a region where the sparse wirings are formed while leaving the sacrificial film filled between the adjacent wirings in the region where the dense wirings are formed;
forming an insulation film above the substrate including the wiring pattern and the remaining sacrificial film;
forming a mask above the insulation film such that the insulation film is partially exposed at a part of the region where the dense wirings are formed and the insulation film is exposed at the region where the sparse wirings are formed;
etching the exposed insulation film using the mask;
removing the sacrificial film through the part of the region where the dense wirings are formed, in which the insulation film has been etched away, so that an air gap is formed between the adjacent wirings in the region where the dense wirings are formed; and
forming an embedded insulation film above the substrate to fill a gap between the adjacent wirings in the region where the sparse wirings are formed after forming the air gap between the adjacent wirings in the region where the dense wirings are formed.

2. The method of manufacturing an electronic part according to claim 1,
wherein the sacrificial film is a carbon film.

3. The method of manufacturing an electronic part according to claim 2,
wherein the insulation film is a silicon oxide film, and
the removing of the sacrificial film formed above the wiring pattern and between the adjacent wirings in the region where the sparse wirings are formed and the forming of the insulation film are performed by supplying oxygen plasma to a same chamber.

4. The method of manufacturing an electronic part according to claim 3,
wherein the removing of the sacrificial film, formed above the wiring pattern and between the adjacent wirings in the region where the sparse wirings are formed, is performed by placing the substrate in a chamber of an atomic layer deposition apparatus and executing an oxygen plasma process at room temperature, and
the forming of the insulation film is performed by causing oxygen plasma and silicon raw material gas to alternately flow at a temperature in the range from the room temperature to about 100° C. in the chamber of the atomic layer deposition apparatus.

5. The method of manufacturing an electronic part according to claim 1,
wherein the embedded insulation film is formed using a chemical vapor deposition method.

6. The method of manufacturing an electronic part according to claim 1,
wherein, in the etching of the insulation film, the exposed insulation film in the region where the sparse wirings are formed is etched, so that a spacer film is formed at sidewalls of the sparse wirings.

7. The method of manufacturing an electronic part according to claim 6,
wherein the spacer film is tapered at an upper end thereof.

8. The method of manufacturing an electronic part according to claim 1,
wherein, in the forming of the mask, the mask is formed such that the insulation film is exposed in a partial region with no air gap, out of the region where the dense wirings are formed.

9. The method of manufacturing an electronic part according to claim 2,
wherein, in the forming of the air gap, the sacrificial film is removed by oxygen plasma.

10. The method of manufacturing an electronic part according to claim 9,
wherein the mask is resist, and
in the forming of the air gap, the sacrificial film and the mask are simultaneously removed.

11. The method of manufacturing an electronic part according to claim 1,
wherein the substrate is a semiconductor substrate,
the process target is a non-volatile semiconductor memory device having a structure in which a predetermined number of cell units are arranged in a first direction to constitute a block, each of the cell units comprising:
a plurality of memory cells including a predetermined number of memory cell transistors connected in series to one another in a second direction perpendicular to the first direction, each of the memory cell transistors including a stack gate structure, in which a tunnel insulation film, a floating gate electrode film, an inter-electrode insulation film, and a control gate electrode are sequentially stacked, and source/drain regions formed on a surface of the semiconductor substrate at both sides of the stack gate structure in the second direction; and
selection gate transistors, which are arranged at both ends of the plurality of the memory cells, each including a gate structure, in which the tunnel insulation film, the floating gate electrode film, the inter-electrode insulation film formed with an opening passing through in a thickness direction, and the control gate electrode are stacked, and source/drain regions formed on the surface of the semiconductor substrate at both sides of the gate structure in the second direction,
the memory cell transistors arranged in the first direction being connected to one another through a word line, and the selection gate transistors arranged in the first direction being connected to one another through a selection gate line,
the dense wirings are the stack gate structure connected by the word line, and
the sparse wirings are the gate structure connected by the selection gate line.

12. The method of manufacturing an electronic part according to claim 11,
wherein, in the forming of the mask, the mask is not formed above a drawing part at an end in the first direction of the word line such that the insulation film is partially exposed at a part of the region where the dense wirings are formed.

13. The method of manufacturing an electronic part according to claim 11,
wherein a distance between side surfaces, facing each other in the second direction, of two adjacent word lines is approximately equal to a width of the word line, and
a distance between side surfaces facing each other in the second direction of the word line and the selection gate line, which are adjacent to each other, is approximately equal to or less than twice the width of the word line.

14. The method of manufacturing an electronic part according to claim 13,
wherein, in the forming of the sacrificial film, a thickness of the sacrificial film is set to be in a range of from a half to the same level of the width of the word line.

15. The method of manufacturing an electronic part according to claim 13,
wherein, as the block, a plurality of blocks are arranged in the second direction at a predetermined interval, and
a distance between side surfaces, facing each other in the second direction, of two selection gate lines of adjacent blocks is larger than twice the width of the word line.

16. The method of manufacturing an electronic part according to claim 15,
wherein, in the forming of the insulation film, the insulation film is formed to cover a side portion of adjacent selection gate lines between different blocks and a bottom portion between the adjacent selection gate lines, and the insulation film is formed to cover upper surfaces of selection gate lines, upper surfaces of word lines, and an upper surface of the sacrificial film at other parts, and
in the etching of the insulation film, the insulation film exposed between the different blocks is etched, so that a spacer film is formed at side surfaces of the adjacent selection gate lines.

17. The method of manufacturing an electronic part according to claim 13,
wherein, as the block, a plurality of blocks are arranged in the second direction at a predetermined interval, and
in the forming of the mask, the mask is not formed between the blocks adjacent in the second direction such that the insulation film is exposed in the region where the sparse wirings are formed.

18. The method of manufacturing an electronic part according to claim 17,
wherein the air gap is formed between the two adjacent word lines and between the word line and the selection gate line, which are adjacent to each other.

19. The method of manufacturing an electronic part according to claim 13,
wherein, as the block, a plurality of blocks are arranged in the second direction at a predetermined interval, and
in the forming of the mask, the mask is not formed at an outer side beyond the word line of an end in the second direction of the block and between the blocks adjacent in the second direction such that the insulation film is exposed in the region where the sparse wirings are formed.

20. The method of manufacturing an electronic part according to claim 19,
wherein the air gap is formed between the two adjacent word lines.
